(19) United States
(12) Patent Application Publication
(10) Pub. No.: US 2015/0303055 A1
(43) Pub. Date: Oct. 22, 2015

(54) METHODS FOR FABRICATING INTEGRATED CIRCUITS INCLUDING SURFACE TREATING FOR DIRECTED SELF-ASSEMBLY

(71) Applicant: GLOBALFOUNDRIES, Inc., Grand Cayman (KY)

(72) Inventors: Ji Xu, Watervliet, NY (US); Gerard Schmid, Guilford, CT (US); Richard A. Farrell, Albany, NY (US)

(73) Assignee: GLOBALFOUNDRIES, Inc., Grand Cayman (KY)

(21) Appl. No.: 14/254,460

(22) Filed: Apr. 16, 2014

(51) Int. Cl. H01L 21/027; H01L 21/02

(52) U.S. Cl. CPC H01L 21/0276; H01L 21/02348

(57) ABSTRACT

Methods for fabricating integrated circuits are provided. In one example, a method for fabricating an integrated circuit includes surface treating exposed portions of an anti-reflective coating (ARC) that overlie a semiconductor substrate to form surface treated ARC portions. A neutral layer is formed overlying the anti-reflective coating including over the surface treated ARC portions. First portions of the neutral layer are selectively removed and second portions of the anti-reflective coating that are disposed under the first portions laterally adjacent to the surface treated ARC portions are exposed to define a guide pattern. A block copolymer layer is deposited overlying the guide pattern. The block copolymer layer is phase separated to define a nanopattern that is registered to the guide pattern.

### TECHNICAL FIELD

The technical field relates generally to methods for fabricating integrated circuits, and more particularly relates to methods for fabricating integrated circuits including surface treating for improved guide pattern formation for directed self-assembly.

### BACKGROUND

Decreasing device size and increasing device density has traditionally been a high priority for the manufacturing of integrated circuits. Optical lithography has been the driving force for device scaling. Conventional optical lithography is limited to about 80 nm pitch for single exposure patterning. While double and other multi-patterning processes can realize smaller pitch, these approaches are expensive and more complex.

Directed self-assembly (DSA), a technique which aligns self-assembling polymeric materials on a lithographically-defined guide pattern, is a potential option for extending current optical lithography beyond its pitch and resolution limits. The self- assembling materials, for example, are block copolymers (BCPs) that consist of “A” homopolymers covalently attached to “B” homopolymers, which are coated over a lithographically defined guide pattern on a semiconductor substrate. The lithographically defined guide pattern is a pre-pattern that is encoded with spatial chemical and/or topographical information and serves to direct the self-assembly process and the pattern formed by the self-assembling materials. Subsequently, by annealing the DSA polymers, the A polymer chains and the B polymer chains undergo phase separation to form an A polymer region and a B polymer region that are registered to the guide pattern. Then, by removing either the A polymer region or the B polymer region by wet chemical or plasma-etch techniques, a mask is formed for transferring the nanopattern to the underlying substrate.

In one DSA technique, an anti-reflective coating (ARC) of, for example, a polymer and/or silicon containing material, is formed overlying a semiconductor substrate for absorbing and/or controlling light to dampen or eliminate light reflection during photolithography to improve the photolithography process window for producing smaller features. A functionally reactive neutral layer-forming material, such as a random copolymer with reactive functional groups, is deposited overlying the anti-reflective coating and is heated to cross-link and/or graft the random copolymer to form a neutral layer (e.g., chemically neutral layer that exhibits minimal or no preferential affinity towards the A polymer chains and B polymer chains of a block copolymer for DSA). Portions of the neutral layer are then selectively removed to define a guide pattern for directing a block copolymer subsequently deposited thereon to form a nanopattern during the directed self-assembly process. Unfortunately, during deposition and/or heating of the neutral layer-forming material, the neutral layer-forming material may dewet or pullback from the anti-reflective coating, thereby unintentionally exposing additional portions of the anti-reflective coating and negatively impacting guide pattern formation including the accuracy and quality of the resulting guide pattern.

Accordingly, it is desirable to provide methods for fabricating integrated circuits with improved guide pattern formation for directed self-assembly. Furthermore, other desirable features and characteristics of the present invention will become apparent from the subsequent detailed description and the appended claims, taken in conjunction with the accompanying drawings and this background.

### BRIEF SUMMARY

Methods for fabricating integrated circuits are provided herein. In accordance with an exemplary embodiment, a method for fabricating an integrated circuit includes surface treating exposed portions of an anti-reflective coating (ARC) that overlie a semiconductor substrate to form surface treated ARC portions. A neutral layer is formed overlying the anti-reflective coating including over the surface treated ARC portions. First portions of the neutral layer are selectively removed and second portions of the anti-reflective coating that are disposed under the first portions laterally adjacent to the surface treated ARC portions are exposed to define a guide pattern. A block copolymer layer is deposited overlying the guide pattern. The block copolymer layer is phase separated to define a nanopattern that is registered to the guide pattern.

In accordance with another exemplary embodiment, a method for fabricating an integrated circuit is provided. The method includes adjusting a polarity of a patterned photoresist layer that overlies an anti-reflective coating (ARC) overlying a semiconductor substrate using a flood exposure UV process to form a polarity adjusted, patterned photoresist layer. Exposed portions of the anti-reflective coating are disposed laterally adjacent to the polarity adjusted, patterned photoresist layer. The exposed portions of the anti-reflective coating are surface treated to form surface treated ARC portions. A neutral layer-forming material is conformally deposited and heated overlying the polarity adjusted, patterned photoresist layer and the surface treated ARC portions to form a neutral layer. The polarity adjusted, patterned photoresist layer and first portions of the neutral layer that overlie the polarity adjusted, patterned photoresist layer are removed to expose second portions of the anti-reflective coating that are disposed laterally adjacent to the surface treated ARC portions to define a guide pattern. A block copolymer layer is deposited overlying the guide pattern. The block copolymer layer is phase separated to define a nanopattern that is registered to the guide pattern.

In accordance with another exemplary embodiment, a method for fabricating an integrated circuit is provided. The method includes exposing a polarity adjusted, patterned photoresist layer that overlies an anti-reflective coating (ARC) overlying a semiconductor substrate to a surface treatment process to reduce a critical dimension (CD) of the polarity adjusted, patterned photoresist layer and form a reduced CD-polarity adjusted, patterned photoresist layer. A neutral layer is formed overlying the reduced CD-polarity adjusted, patterned photoresist layer and the anti-reflective coating. The reduced CD-polarity adjusted, patterned photoresist layer and first portions of the neutral layer that overlie the reduced CD-polarity adjusted, patterned photoresist layer are removed to expose second portions of the anti-reflective coating while leaving third portions of the neutral layer that are disposed laterally adjacent to the second portions intact to form a guide pattern. A block copolymer layer is deposited overlying the guide pattern. The block copolymer layer is phase separated to define a nanopattern that is registered to the guide pattern.

### BRIEF DESCRIPTION OF THE DRAWINGS

The various embodiments will hereinafter be described in conjunction with the following drawing figures, wherein like numerals denote like elements, and wherein:

FIGS. 1-9 illustrate, in cross-sectional views, an integrated circuit and a method for fabricating an integrated circuit during various intermediate fabrication stages in accordance with an exemplary embodiment.

### DETAILED DESCRIPTION

The following Detailed Description is merely exemplary in nature and is not intended to limit the various embodiments or the application and uses thereof. Furthermore, there is no intention to be bound by any theory presented in the preceding background or the following detailed description.

Various embodiments contemplated herein relate to methods for fabricating integrated circuits. The exemplary embodiments taught herein provide an anti-reflective coating (ARC) that overlies a semiconductor substrate. Exposed portions of the anti- reflective coating are surface treated to form surface treated ARC portions. In an exemplary embodiment, the exposed portions of the anti-reflective coating are surface treated using an UV treatment process, a plasma treatment process, an UV ozone treatment process, or a reactive ion exchange (RIE) process. A neutral layer is formed overlying the anti-reflective coating including over the surface treated ARC portions. In an exemplary embodiment, the neutral layer is formed by conformally depositing and heating a neutral layer-forming material overlying the anti-reflective coating including on the surface treated ARC portions. First portions of the neutral layer are selectively removed and second portions of the anti-reflective coating that are disposed under the first portions laterally adjacent to the surface treated ARC portions are exposed to define a guide pattern. A block copolymer layer is deposited overlying the guide pattern and is phase separated to define a nanopattern that is registered to the guide pattern. It has been found that by surface treating the anti-reflective coating, the surface tension between the surface treated ARC portions of the anti-reflective coating and the neutral layer-forming material is reduced to improve wetting (e.g., reduce dewetting or pulling-back) of the neutral layer- forming material on the surface treated ARC portions during formation of the neutral layer. As such, additional portions of the anti-reflective coating are not unintentionally exposed, thereby improving guide pattern formation including enhancing the accuracy and quality of the resulting guide pattern.

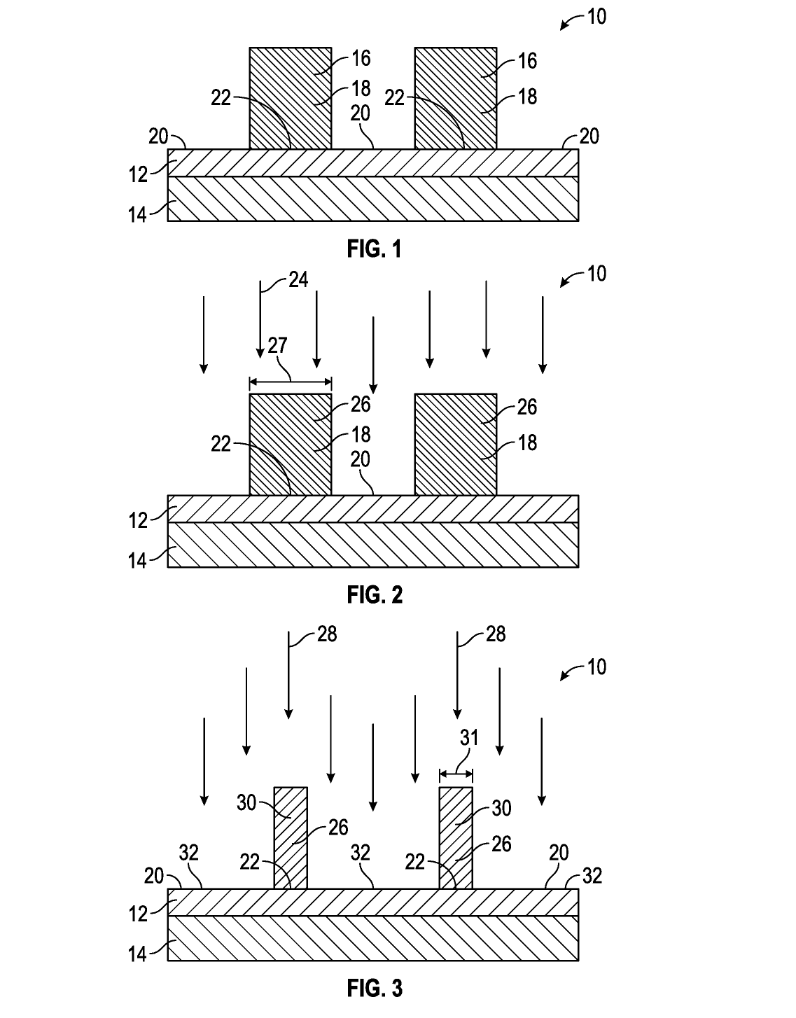

FIGS. 1-9 illustrate methods for fabricating an integrated circuit 10 in accordance with various embodiments. The described process steps, procedures, and materials are to be considered only as exemplary embodiments designed to illustrate to one of ordinary skill in the art methods for practicing the invention; the invention is not limited to these exemplary embodiments. Various steps in the manufacture of integrated circuits are well known and so, in the interest of brevity, many conventional steps will only be mentioned briefly herein or will be omitted entirely without providing the well-known process details.

FIG. 1 illustrates, in cross-sectional view, a portion of the integrated circuit (IC) 10 during an intermediate fabrication stage in accordance with an exemplary embodiment. As illustrated, the IC 10 includes an anti-reflective coating 12 disposed on a semiconductor substrate 14. As used herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In an addition, “semiconductor material” encompasses other materials such as relatively pure and impurity-doped germanium, gallium arsenide, zinc oxide, glass, and the like. The semiconductor material is preferably a silicon substrate. The semiconductor substrate 14 may be a bulk silicon wafer or may be a thin layer of silicon on an insulating layer (commonly known as silicon-on-insulator or SOI) that, in turn, is supported by a carrier wafer.

The anti-reflective coating 12 (ARC) may be a polymer and/or silicon (Si) containing material that is used to absorb and/or control light to dampen or eliminate light reflection during photolithography to improve the photolithography process window for producing smaller features. In one embodiment, the anti-reflective coating 12 is formed of a Si-containing polymer(s) (SiARC) that may be cross-linked. SiARC materials are commercially available from several manufacturers including Shin Etsu Chemical Co., Ltd., which is headquartered in Japan. In another embodiment, the anti-reflective coating 12 is formed of silicon oxynitride (SiON). The anti-reflective coating 12 may be formed by depositing an anti-reflective material onto the semiconductor substrate 14 using a spin coating process or a plasma deposition process, for example, and heating the semiconductor substrate 14 to cross-link the anti-reflective material. In an exemplary embodiment, the semiconductor substrate 14 with the anti-reflective material is heated to a temperature of from about 150° C. to about 350° C. to cross-link the anti-reflective material and form the anti-reflective coating 12.

Overlying the anti-reflective coating 12 is a photoresist layer 16. The photoresist layer 16 may be deposited using a well-known deposition technique, e.g., a spin coating process or the like. The photoresist layer 16 is then patterned, for example, using a well-known lithographic technique, e.g., an ultraviolet (UV) lithographic process, a deep ultraviolet (DUV) lithographic process, an extreme ultraviolet (EUV) lithographic process or the like, to form a patterned photoresist layer 18. In an exemplary embodiment, the patterned photoresist layer 18 is formed using a 193 nm immersion UV process or alternatively, an EUV process. As illustrated, portions 20 of the anti-reflective coating 12 are exposed while portions 22 of the anti-reflective coating 12 are covered by the patterned photoresist layer 18.

The process continues as illustrated in FIG. 2 by exposing the IC 10 to a flood exposure UV process using UV light (indicated by arrows 24) to adjust the polarity of the patterned photoresist layer 18 to form a polarity adjusted, patterned photoresist layer 26. In an exemplary embodiment, the patterned photoresist layer 18 is substantially soluble in an organic solvent, such as propylene glycol methyl ether acetate (PGMEA), 4-methyl-2-pentanol, n-butyl acetate, gamma-butyrolactone, toluene, acetone, and/or the like, but substantially insoluble in an aqueous-based solvent. The polarity of the patterned photoresist layer 18 is adjusted such that the polarity adjusted, patterned photoresist layer 26 is substantially soluble in an aqueous-based solvent and is substantially insoluble in an organic solvent, such as PGMEA, 4-methyl-2-pentanol, n-butyl acetate, gamma-butyrolactone, toluene, acetone, and/or the like. In an exemplary embodiment, the flood exposure UV process 24 uses UV light at a wavelength of from about 190 to about 400 nm with an exposure dose of about 5 to about 40 mJ/cm², for example about 20 mJ/cm². As illustrated, the polarity adjusted, patterned photoresist layer 26 has a critical dimension (CD) (indicated by double headed arrow 27) of from about 35 to about 50 nm.

FIG. 3 illustrates, in cross-sectional view, the IC 10 during a further advanced fabrication stage in accordance with an exemplary embodiment. The polarity adjusted, patterned photoresist layer 26 and the portions 20 of the anti-reflective coating 12 are exposed to a surface treatment process (indicated by arrows 28) to reduce the CD of the polarity adjusted, patterned photoresist layer 26 and increase the surface energy of the portions 20 to form a reduced CD-polarity adjusted, patterned photoresist layer 30 and surface treated ARC portions 32, respectively. In an exemplary embodiment, the surface treatment process 28 is an UV treatment process, a plasma treatment process, an UV ozone treatment process, or a reactive ion exchange (RIE) process. In an exemplary embodiment, the reduced CD-polarity adjusted, patterned photoresist layer 30 has a CD (indicated by double headed arrow 31) of from about 5 to about 25 nm, such as from about 10 to about 20 nm. Reducing the CD of the polarity adjusted, patterned photoresist layer 26 helps further improve device scaling and smaller pitch over conventional lithographic processes.

In an exemplary embodiment, the surface treatment process 28 oxidizes the portions 20 of the anti-reflective coating 12 forming the surface treated ARC portions 32 with hydroxyl (—OH) moieties. It has been found that by oxidizing the portions 20 of the anti-reflective coating 12, the surface energy of the surface treated ARC portions 32 is increased, reducing the surface tension and improving the wettability of the surface treated ARC portions 32. In an exemplary embodiment, the surface treatment process 28 uses oxygen as a precursor gas and is an O₂ plasma treatment process, an UV ozone treatment process, or an O₂ reactive ion exchange (RIE) treatment process.

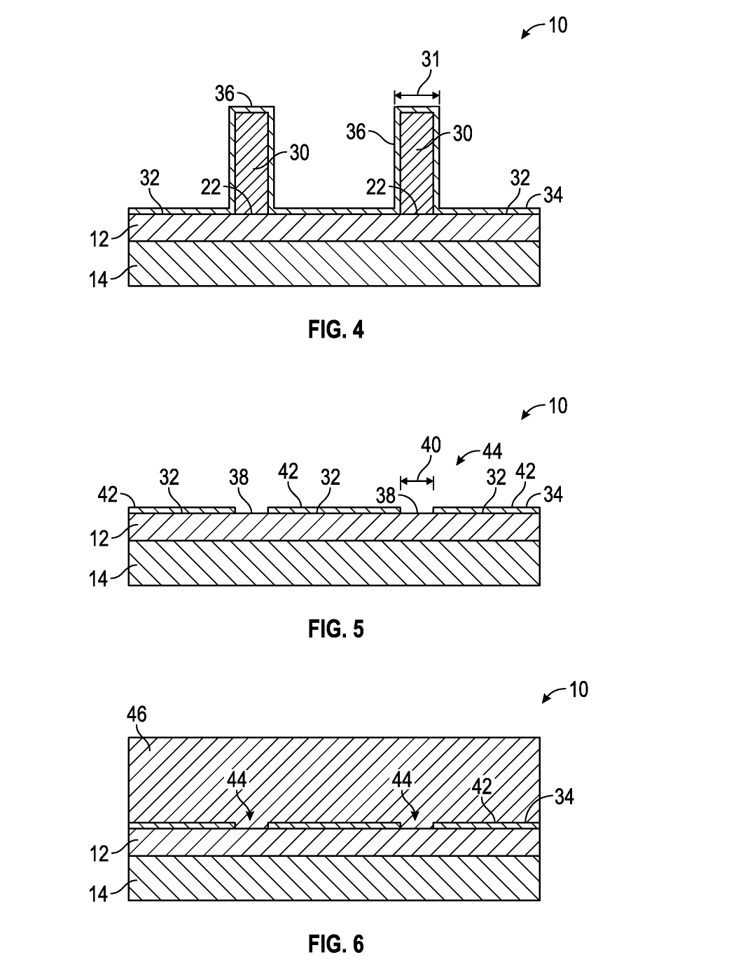

The process continues as illustrated in FIG. 4 by conformally depositing and heating a neutral layer-forming material to form a neutral layer 34. In an exemplary embodiment, the neutral layer 34 has no preferential affinity for the individual polymeric block components of a block copolymer that will be subsequently deposited over the neutral layer 34 as part of a DSA process as will be discussed in further detail below. In an exemplary embodiment, the neutral layer-forming material is a random copolymer with reactive functional groups, such as hydroxyl (—OH) moieties, that cross-link or graft to the surface treated ARC portions 32. In one example, the neutral layer-forming material is a polystyrene-(random)-polymethylmethacrylate (PS-r-PMMA) copolymer with —OH moieties.

In an exemplary embodiment, the neutral layer-forming material is dissolved in an organic solvent, such as PGMEA, 4-methyl-2-pentanol, n-butyl acetate, gamma-butyrolactone, toluene, acetone, and/or the like, and is conformally deposited on the IC 10 overlying the surface treated ARC portions 32 and the reduced CD-polarity adjusted, patterned photoresist layer 30 using a spin coating process. In an exemplary embodiment, after deposition, the neutral layer-forming material is heated to a temperature of from about 100 to about 350° C. to remove the organic solvent and cross-link and/or graft the neutral layer-forming material. In an exemplary embodiment, the neutral layer 34 has a thickness of from about 5 to about 10 nm. In an exemplary embodiment, it has been found that because of the increased surface energy and reduced surface tension of the surface treated ARC portions 32 of the anti-reflective coating 12, the neutral layer-forming material substantially wets out the surface treated ARC portions 32 during formation of the neutral layer 32 so as to not unintentionally expose the underlying anti-reflective coating 12, thereby improving subsequent guide pattern formation as will be discussed in further detail below.

Referring to a FIGS. 4-5, the reduced CD-polarity adjusted, patterned photoresist layer 30 and portions 36 of the neutral layer 34 that overlie the reduced CD-polarity adjusted, patterned photoresist layer 30 are removed to selectively expose portions 38 of the anti-reflective coating 12 that are disposed laterally adjacent to the surface treated ARC portions 32. In an exemplary embodiment, the reduced CD-polarity adjusted, patterned photoresist layer 30 is exposed to and dissolved in an aqueous-based solvent to remove the reduced CD-polarity adjusted, patterned photoresist layer 30 and lift off the portions 36 of the neutral layer 34. In one embodiment, the aqueous-based solvent is an aqueous mixture including water and tetramethylammonium hydroxide (TMAOH) that is present in an amount of from about 0.5 to about 2.5 wt. % of the aqueous mixture.

The remaining portions 42 of the neutral layer 34 and the portions 38 of the anti-reflective coating 12 together define a guide pattern 44. As illustrated, the CD (indicated by double headed arrow 40) of the portions 38 substantially matches the CD 31 of the reduced CD-polarity adjusted, patterned photoresist layer 30. As such, in an exemplary embodiment, the guide pattern 44 can be used to form smaller pitch device features compared to conventional DSA guide patterns.

FIGS. 6-9 illustrate, in cross-sectional views, the IC 10 during later fabrication stages in accordance with an exemplary embodiment. The method continues by depositing a block copolymer layer 46 overlying the guide pattern 44 as illustrated in FIG. 6. The block copolymer layer 46 may be deposited, for example, using a spin coating process or the like. The block copolymer layer 46 has A polymer blocks and B polymer blocks. In an exemplary embodiment, the block copolymer layer 46 is a block copolymer of polystyrene that forms the A polymer blocks (e.g., etch resistant blocks) and polymethylmethacrylate that forms the B polymer blocks (e.g., etchable blocks).

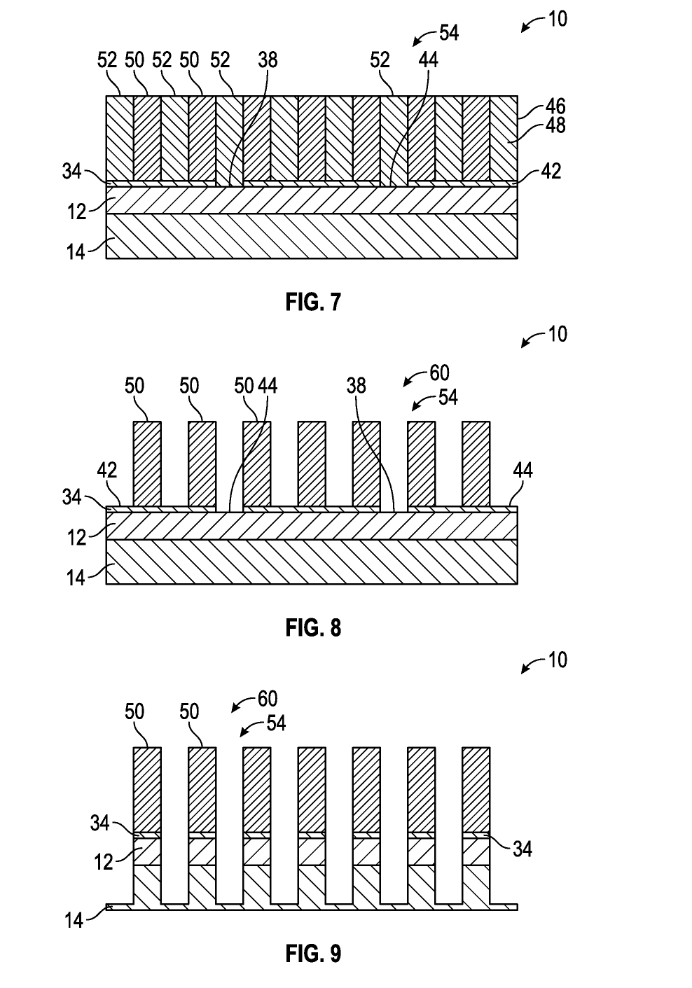

The block copolymer layer 46 is heated at a predetermined temperature for a predetermined time to phase separate the block copolymer layer 46 and form a phase separated block copolymer 48 as illustrated in FIG. 7. The phase separated block copolymer 48 has A polymer block regions 50 (e.g., etch resistant/non-degradable block regions) formed from the A polymer blocks and B polymer block regions 52 (e.g., etchable/degradable block regions) formed from the B polymer blocks. In an exemplary embodiment, the remaining portions 42 of the neutral layer 34 and the portions 38 of the anti-reflective coating 12 of the guide pattern 44 have different affinities towards the A polymer blocks and independently towards the B polymer blocks of the block copolymer layer 46. As such, when the block copolymer layer 46 phase separates, the A polymer block regions 50 and the B polymer block regions 52 are registered to the guide pattern 44 so as to produce a nanopattern 54. In an exemplary embodiment, the block copolymer layer 46 is heated at a temperature of from about 200 to about 350° C. for about 60 to about 600 seconds in a nitrogen-rich (N₂) atmosphere. In an exemplary embodiment, the nanopattern 54 allows for resolution in the nanometer range beyond that of conventional optical lithography techniques.

The method continues as illustrated in FIG. 8 by removing the B polymer block regions 52. As illustrated, the remaining A polymer block regions 50 defines a mask 60 for transferring the nanopattern 54 to the semiconductor substrate 14. In an exemplary embodiment, the B polymer block regions 52 are polymethylmethacrylate and are removed by exposing the phase separated block copolymer 48 (see FIG. 7) to a dry etching process, such as reactive-ion etching (RIE) plasma. The nanopattern 54 is transferred to the semiconductor substrate 14 as illustrated in FIG. 9 to form device features, for example, using the mask 60 and a conventional wet or dry etching process.

Accordingly, methods for fabricating integrated circuits including surface treating for improved guide pattern formation for directed self-assembly have been described.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

1. A method for fabricating an integrated circuit comprising:
surface treating exposed portions of an anti-reflective coating (ARC) that overlie a semiconductor substrate to form surface treated ARC portions;
forming a neutral layer overlying the anti-reflective coating including over the surface treated ARC portions;
selectively removing first portions of the neutral layer to expose second portions of the anti-reflective coating that are disposed under the first portions laterally adjacent to the surface treated ARC portions to define a guide pattern comprising the second portions of the anti-reflective coating that are exposed and remaining portions of the neutral layer that are exposed and that are disposed on the surface treated ARC portions laterally adjacent to the second portions of the anti-reflective coating;
depositing a block copolymer layer overlying the guide pattern; and
phase separating the block copolymer layer to define a nanopattern that is registered to the guide pattern.

2. The method of claim 1, wherein surface treating comprises exposing the exposed portions of the anti-reflective coating to an UV treatment process, a plasma treatment process, an UV ozone treatment process, or a reactive ion exchange (RIE) process.

3. The method of claim 1, wherein surface treating comprises oxidizing the exposed portions of the anti-reflective coating.

4. The method of claim 3, wherein oxidizing the exposed portions comprises exposing the exposed portions of the anti-reflective coating to an O₂ plasma treatment process, an UV ozone treatment process, or an O₂ reactive ion exchange (RIE) treatment process.

5. The method of claim 3, wherein oxidizing comprises forming the surface treated ARC portions containing hydroxyl (—OH) moieties.

6. The method of claim 1, further comprising:
depositing the anti-reflective coating comprising a silicon-containing material overlying the semiconductor substrate.

7. The method of claim 6, wherein depositing comprises depositing the silicon-containing material that comprises silicon oxynitride.

8. The method of claim 1, wherein phase separating comprises phase separating the block copolymer layer into etchable/degradable block regions and etch resistant/non-degradable block regions, and wherein the method further comprises:
removing the etchable/degradable block regions to form a mask for transferring the nanopattern to the semiconductor substrate.

9. A method for fabricating an integrated circuit comprising:
adjusting a polarity of a patterned photoresist layer that overlies an anti-reflective coating (ARC) overlying a semiconductor substrate using a flood exposure UV process to form a polarity adjusted, patterned photoresist layer, wherein exposed portions of the anti-reflective coating are disposed laterally adjacent to the polarity adjusted, patterned photoresist layer;
surface treating the exposed portions of the anti-reflective coating to form surface treated ARC portions;
conformally depositing and heating a neutral layer-forming material overlying the polarity adjusted, patterned photoresist layer and the surface treated ARC portions to form a neutral layer;
removing the polarity adjusted, patterned photoresist layer and first portions of the neutral layer that overlie the polarity adjusted, patterned photoresist layer to expose second portions of the anti-reflective coating that are disposed laterally adjacent to the surface treated ARC portions to define a guide pattern comprising the second portions of the anti-reflective coating that are exposed and remaining portions of the neutral layer that are exposed and that are disposed on the surface treated ARC portions laterally adjacent to the second portions of the anti-reflective coating;
depositing a block copolymer layer overlying the guide pattern; and
phase separating the block copolymer layer to define a nanopattern that is registered to the guide pattern.

10. The method of claim 9, wherein adjusting the polarity comprises adjusting the polarity of the patterned photoresist layer such that the polarity adjusted, patterned photoresist layer is substantially insoluble in a first solvent and is substantially soluble in a second solvent, wherein conformally depositing comprises conformally depositing the neutral layer-forming material that comprises the first solvent, and wherein removing comprises dissolving the polarity adjusted, patterned photoresist layer in the second solvent.

11. The method of claim 10, wherein conformally depositing comprises conformally depositing the neutral layer-forming material that comprises an organic solvent as the first solvent, and wherein removing comprises dissolving the polarity adjusted, patterned photoresist layer in an aqueous-based solvent as the second solvent.

12. The method of claim 11, wherein removing comprises dissolving the polarity adjusted, patterned photoresist layer in the aqueous-based solvent that comprises water and tetramethylammonium hydroxide (TMAOH) that is present in an amount of from about 0.5 to about 2.5 wt. % of the aqueous-based solvent.

13. The method of claim 9, wherein heating the neutral layer-forming material comprises heating the neutral layer-forming material at a temperature of from about 100 to about 350° C.

14. The method of claim 9, wherein surface treating comprises exposing the polarity adjusted, patterned photoresist layer to a surface treatment process to reduce a critical dimension (CD) of the polarity adjusted, patterned photoresist layer and form a reduced CD-polarity adjusted, patterned photoresist layer, and wherein the surface treated ARC portions are disposed laterally adjacent to the reduced CD-polarity adjusted, patterned photoresist layer.

15. The method of claim 14, wherein conformally depositing and heating comprises conformally depositing and heating the neutral layer-forming material overlying the reduced CD-polarity adjusted, patterned photoresist layer, and wherein removing comprises removing the reduced CD-polarity adjusted, patterned photoresist layer to expose the second portions of the anti-reflective coating that has a reduced critical dimension that substantially matches the critical dimension of the reduced CD-polarity adjusted, patterned photoresist layer.

16. The method of claim 9, further comprising:
patterning a photoresist layer that overlies the anti-reflective coating using a 193 nm immersion UV process to form the patterned photoresist layer.

17. The method of claim 9, further comprising:
patterning a photoresist layer that overlies the anti-reflective coating using an extreme ultraviolet (EUV) process to form the patterned photoresist layer.

18. A method for fabricating an integrated circuit comprising:
exposing a polarity adjusted, patterned photoresist layer that overlies an anti- reflective coating (ARC) overlying a semiconductor substrate to a surface treatment process to reduce a critical dimension (CD) of the polarity adjusted, patterned photoresist layer and form a reduced CD-polarity adjusted, patterned photoresist layer;
forming a neutral layer overlying the reduced CD-polarity adjusted, patterned photoresist layer and the anti-reflective coating;
removing the reduced CD-polarity adjusted, patterned photoresist layer and first portions of the neutral layer that overlie the reduced CD-polarity adjusted, patterned photoresist layer to expose second portions of the anti-reflective coating while leaving third portions of the neutral layer that are disposed laterally adjacent to the second portions intact to form a guide pattern comprising the second portions of the anti-reflective coating that are exposed and the third portions of the neutral layer that are exposed and that are disposed on the surface treated ARC portions laterally adjacent to the second portions of the anti-reflective coating;
depositing a block copolymer layer overlying the guide pattern; and
phase separating the block copolymer layer to define a nanopattern that is registered to the guide pattern.

19. The method of claim 18, wherein exposing comprises exposing the polarity adjusted, patterned photoresist layer having the critical dimension of from about 35 to about 50 nm.

20. The method of claim 18, wherein exposing comprises forming the reduced CD-polarity adjusted, patterned photoresist layer having a reduced critical dimension of from about 5 to about 25 nm.
